(19) United States
(12) Patent Application Publication
(10) Pub. No.: US 2009/0320388 A1
(43) Pub. Date: Dec. 31, 2009

(54) Double-skin and moveable-sunshade facade system

(76) Inventors: Doriano Lilli, Giano dell'Umbria (IT); Lorenzo Lilli, Giano dell'Umbria (IT)

Correspondence Address: ABELMAN, FRAYNE & SCHWAB, 666 THIRD AVENUE, 10TH FLOOR, NEW YORK, NY, 10017, US

(21) Appl. No.: 11/991,050

(22) PCT Filed: Aug. 31, 2006
(86) PCT No.: PCT/IT2006/000635

§ 371 Date: Mar. 11, 2009

(30) Foreign Application Priority Data
Aug. 31, 2005 (IT) PG2005A000041

(51) Int. Cl. E04B 2/88; H01L 31/042; E04B 2/00

(52) U.S. Cl. 52/173.3; 52/235; 52/473

(57) ABSTRACT

A system with moveable surfaces for building facades comprises means that, in combination, are capable of providing a “double-skin” for said facades during the cold season and of shading the facades from the sun during the hot season. Said system comprises a plurality of sunshade slats and of panes in which the sunshade slats and the panes are moveable.

Currently in the building industry, in order to contain the levels of energy consumption both for heating in winter and for conditioning in summer, various systems are used.

In particular, systems are known for reducing energy consumption in winter, referred to as “double-skin systems”, which, however, prove altogether ineffective, if not even deleterious, in summer.

In addition to this, there also exist systems for reducing energy consumption for conditioning in summer consisting of moveable sunshade slats, which, however, prove altogether useless during the winter.

The main purpose of the present invention is to overcome the problems of the systems currently known by providing a system that is effective both in winter and in summer for reducing the energy consumption necessary for conditioning of a building.

This has been obtained, according to the invention by providing a single facade system with moveable surfaces capable of providing a double skin for the building on which it is installed during the cold season and of shading the facade of the building from the sun during the hot season.

The above and further purposes will be understood more clearly with reference to the ensuing description and to the attached figures, which illustrate, purely by way of non-limiting example, a preferred embodiment of the invention.

In the plate of drawings:

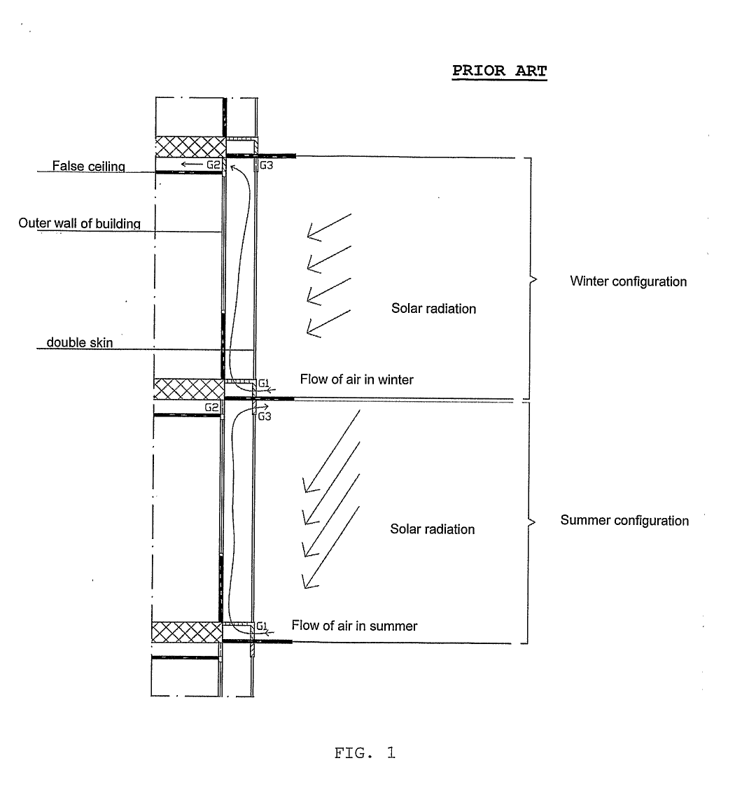

FIG. 1 is a vertical cross-sectional view of a building equipped with a double-skin system of a known type;

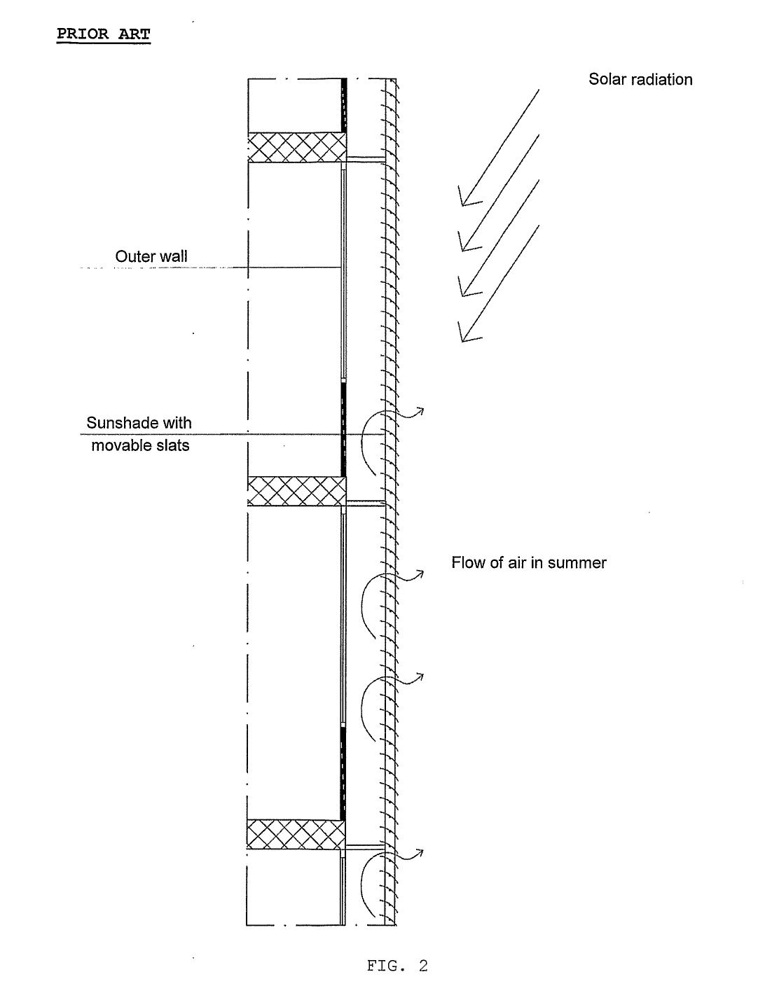

FIG. 2 is a vertical cross-sectional view of a building equipped with a sunshade system of a known type;

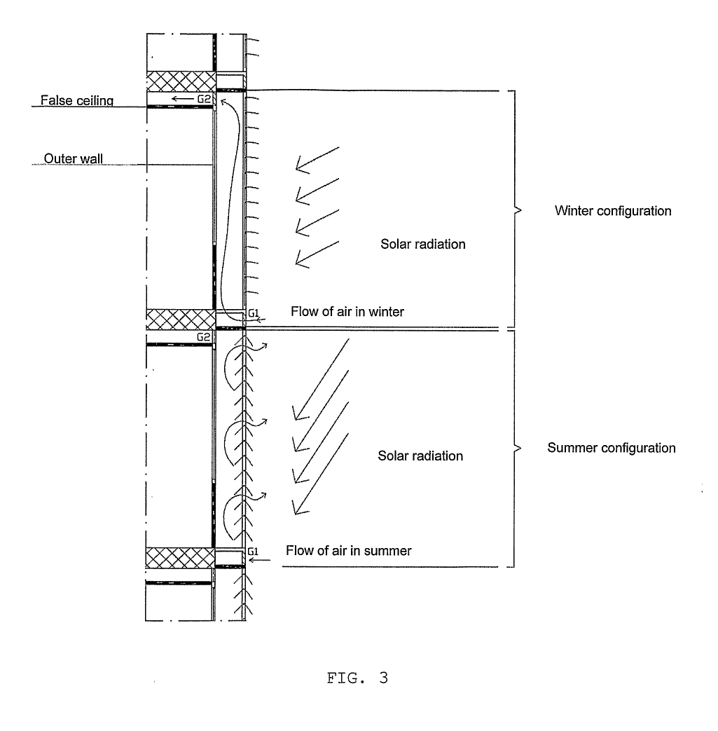

FIG. 3 is a vertical cross-sectional view of a building equipped with a system according to the present invention, in which illustrated in the top part is the system according to the invention in the winter configuration and illustrated in the bottom part is the system according to the invention in the summer configuration;

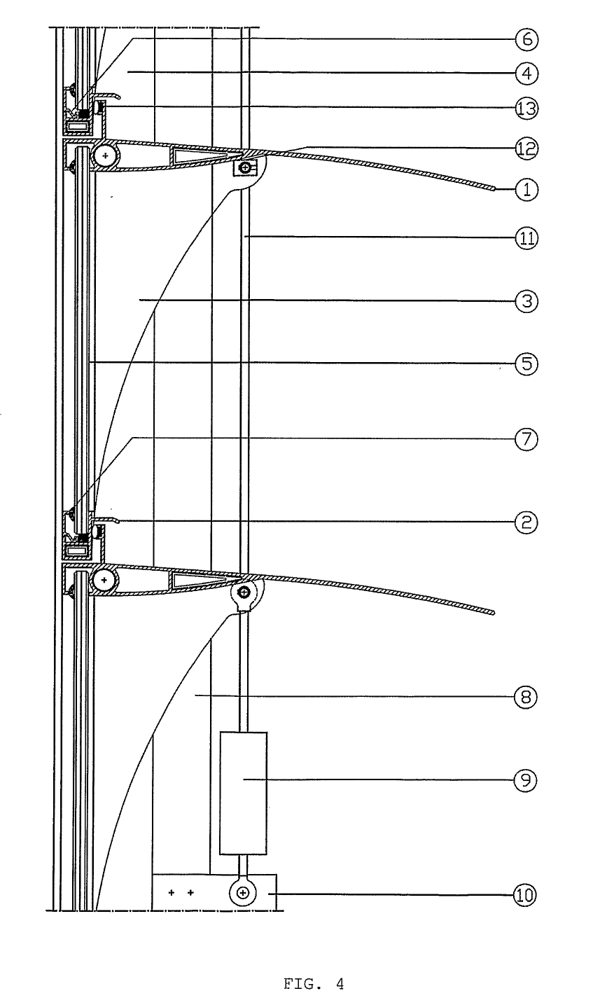

FIG. 4 is a detail of FIG. 3 that shows the invention in the winter configuration;

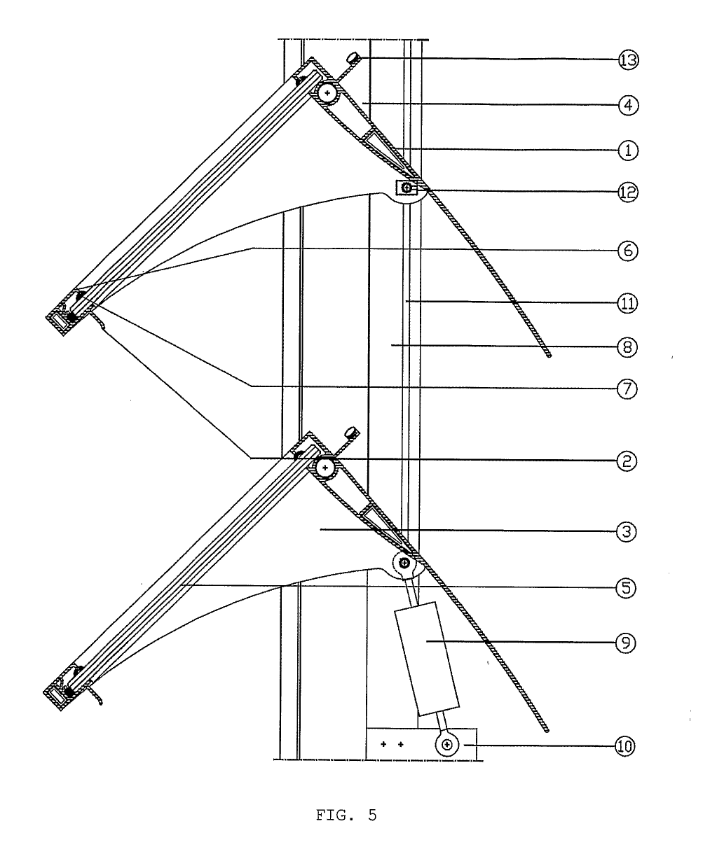

FIG. 5 is a detail of FIG. 3 that shows the invention in the summer configuration;

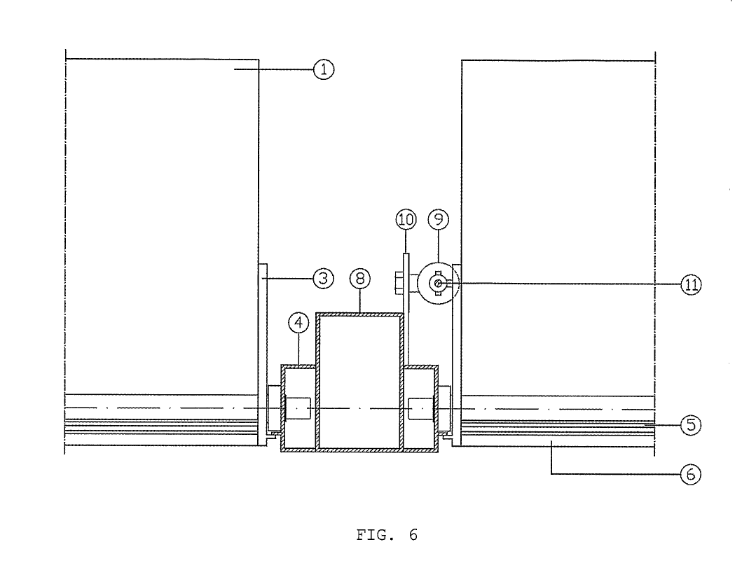

FIG. 6 is a detail in horizontal cross-sectional view that shows the area between two sunshade slats in the winter position;

FIG. 7 is a detail in horizontal cross-sectional view that shows the area between two sunshade slats in the summer position;

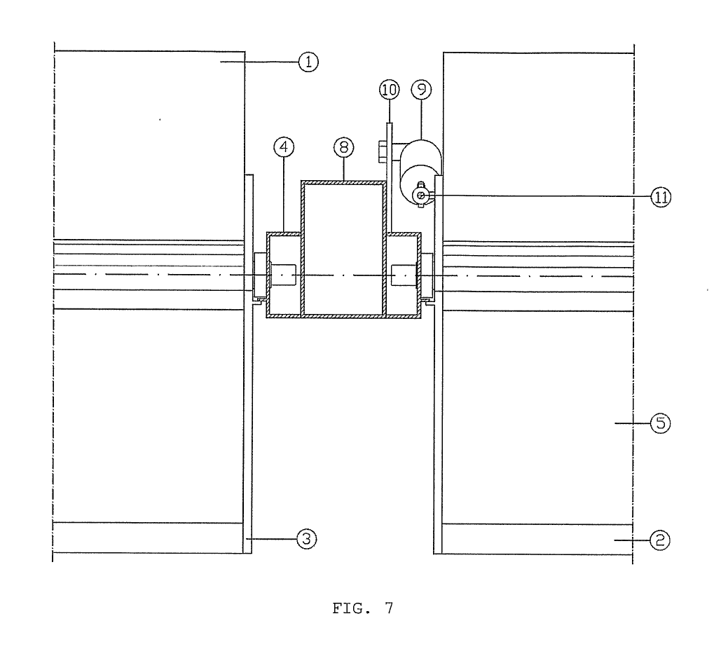

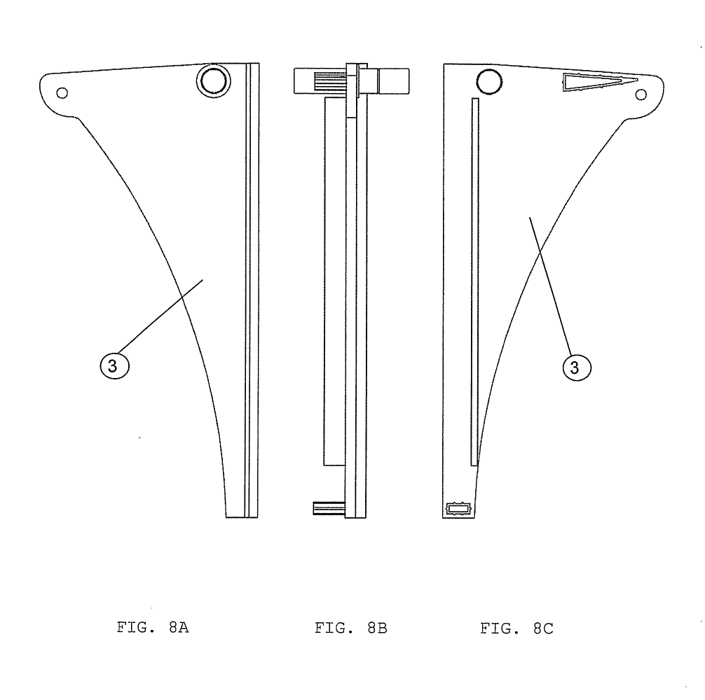

FIGS. 8A, 8B, 8C are, respectively, a right side view, a front view, and a left side view of the end fixing element, or gusset plate, of the sunshade slats and of the panes;

FIG. 9 is a cross-sectional view of a sunshade;

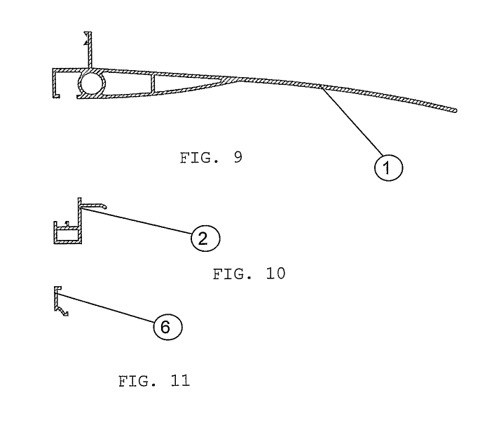

FIG. 10 is a cross-sectional view of the sectional strip for supporting the pane; and

FIG. 11 is a cross-sectional view of the glass stop.

With reference to the figures described above, we have already been able to point out the fact that, in order to reduce the consumption of energy for heating in winter there is an increasingly widespread use of the system referred to as “double skin” (FIG. 1), which basically consists of the application, on the outside of the curtain wall of a building, including the door and window frames, panes, etc., of a second surface or wall, normally glazed (double skin), set at a distance of approximately 500 mm from the first.

The function of the double skin is dual: reducing the dispersion of heat from within the building outwards; and recovering the considerable amount of heat of the flow of air that is generated in the gap between the wall of the building and the double skin.

The air is heated both by the possible solar radiation and by the dispersion of heat through the inside wall.

The flow of air at input from the grating G1 is recovered via the top grating G2 and sent to the central-heating system of the building.

In summer, the grating G2 remains closed, and the flow of air at input from the grating G1 is evacuated through the grating G3.

It is evident that this system is effective in the winter period, but presents limits in the summer period.

For the summer months in fact, instead of the double skin, in many buildings sunshades are applied (FIG. 2).

Normally, the sunshades are made up of moveable slats formed by sectional elements made of aluminium or other sufficiently rigid material. The sunshade slats are connected via a crank mechanism to a motor or manual control that brings about opening or closing thereof according to the inclination of the sun's rays, with the result that the outer wall of the building is kept shaded.

The flow of air that is heated disperses through the sunshade slats.

Sunshades enable an improvement of the living conditions inside the building and in the case where a conditioning system is present also enables a considerable energy saving.

It is, however, evident that the two systems currently known are effective only in the winter period or in the summer period; moreover, since the double skin is a fixed system, it hinders natural ventilation of the building, creating situations of inconvenience to the people inhabiting it, so much so that in some regional contexts the competent authorities have forbidden adoption thereof.

A further purpose of the present invention is to provide a single integrated system, designed to be installed on the outside of buildings, which comprises a plurality of sunshade slats 1 and of panes 5, both moveable, that will enable the benefit of the double-skin facade to be obtained in the winter period and that of the facade with sunshade to be obtained in the summer period, at a cost that is only slightly higher than that of just one of the two systems.

Consequently, according to the energy saving that is achieved throughout the year, the cost of installation is amortized in a few years.

With reference to FIGS. 3 to 11, the system according to the invention comprises a plurality of moveable elements, each of which basically comprises a top sunshade slat 1, fixed to the top edge of which is a pane 5, preferably perpendicular to the sunshade slats themselves.

In the example of embodiment that is described, each moveable element is equipped with two end fixing elements or gusset plates 3 designed to fix together the sunshade slat 1, the pane 5, and a bottom sectional strip 2 designed to support the bottom edge of the pane itself.

Said connection gusset plates 3 are inserted, by means of idle pins, in a side frame 4 that supports the moveable elements themselves, which comprise the sunshade slats 1 and the panes 5.

In particular, the top end of the pane 5 is designed to be inserted in a rear slot of the sunshade slat 1, whilst the bottom end is designed to be inserted in a bottom sectional strip 2, and blocked therein with a purposely provided glass stop 6 and a weather strip 7.

The facade elements, supported by the frame 4, are fixed to an upright 8, which is in turn fixedly anchored to the building in a known way (FIGS. 5, 6 and 7).

The movement of the moveable elements, and consequently of the sunshade slats, is obtained preferably via a motor or other manual member 9, preferably equipped with a crank mechanism, which on one side is fixed to a connection rod 11, which connects the ends of the various moveable elements of each facade element, and on the other is fixed to a metal bracket 10, which is in turn fixed to the upright 8.

To guarantee air- and water-tightness of the system in the winter period, the bottom sectional strip for supporting the pane 2 is equipped with a drip, and is designed to bear upon the sectional strip of the underlying sunshade slat 1 via a purposely provided gasket 13 (FIG. 4).

According to the invention, in the winter period the system is designed to be set in a closed position, i.e., with the sunshade slats 1 in a substantially horizontal position and the panes in a vertical position: in said configuration a double-skin facade is obtained (FIGS. 3 and 4). The sun's rays, with low inclination with respect to the horizon are intercepted only to a minimum extent by the sunshade slats 1, and consequently heat the air in the gap between the panes 5 and the outer facade of the building. In this way, the conditions already described for the double-skin facade are achieved, with all the resulting advantages.

Once again according to the present invention, in the summer period the system is designed to be set in an open position, i.e., with the sunshade slats 1 rotated by an amount necessary for intercepting the sun's rays and for keeping the outer wall of the building in the shade. Said rotation of the sunshade slats 1 is effected by acting on the means of movement 9 and 11 actuated by a purposely provided motor or by a manual control (FIGS. 3 and 5).

The sun's rays with high inclination with respect to the horizon are intercepted completely or almost completely by the sunshade slats 1; consequently, the air in the gap between the panes 5 and the outer facade of the building does not undergo any heating by the sun or undergoes an altogether negligible degree of heating. In said situation, the conditions described for the sunshade slats are achieved, with the advantage that the addition of the pane 5 favours the circulation of the external air, enabling change of air inside the premises of the building.

From what has been said, the effectiveness of the system so far described emerges clearly evident, an effectiveness that results in a considerable energy saving in the running of the building over the entire year and also in an improvement of the living conditions.

According to the invention, the sunshade slats 1 can be made of extruded aluminium sectional strip, plastic material, wood, or other material. Likewise, the side gusset plates 3 that mechanically join the sunshade slats 1, the pane 5, and the bottom sectional strip 2 that supports it, can have the shapes and dimensions desired or required by the particular application, and can be made of plastic material, aluminium, or any other material.

A variant of the invention (not illustrated) envisages providing the sunshade slats 1 with photovoltaic panels for conversion of the solar radiation into electrical energy: in this way, it is possible to increase the energy saving by using the energy thus produced to run the air conditioning.

It is also interesting to note that the presence of the weather stripping 7 and of the contact gaskets 13 enables hermetic closing of said panes on the side supporting frame 4 in order to constitute a shield for the outer walls of the buildings.

Said panes 5, which are preferably anchored to the sunshade slats 1, can be of various dimensions and types: stratified, tempered, stratified and tempered, transparent, coloured, low-emission, etc.

In the preferred embodiment illustrated in the figures, each of the sunshade slats forms a single body with the corresponding pane, and the entire ensemble can turn on a supporting frame via of the pins that enable rotation and corresponding orientation thereof.

In particular, the sunshade slats and the pane that form a single body are connected in series by means of a crank mechanism that enables the simultaneous orientation of the elements made up of a plurality of sunshade slats and of corresponding panes.

Legend of the parts illustrated:

1 Sunshade slat

2 Sectional strip for supporting pane

3 Gusset plate for connection

4 Side frame

5 Pane

6 Glass stop

7 Weather strip

8 Structural tubular element

9 Movement member

10 Motor-anchoring bracket

11 Connection rod

12 Pawl

13 Contact gasket

The present invention has been described and illustrated in a preferred embodiment thereof, but it is clear that a person skilled in the branch may make modifications and/or replacements thereto that are technically and/or functionally equivalent, without thereby departing from the sphere of protection of the present industrial patent right.

1. A system with moveable surfaces for facades of buildings, characterized in that it comprises, in combination, means capable of providing a “double skin” for said facades during the cold season and of shading the facades themselves from the sun during the hot season.

2. The system according to claim 1, characterized in that it comprises a plurality of sunshade slats (1) and of panes (5), in which the sunshade slats and the panes are moveable.

3. The system according to claim 1, characterized in that it comprises a plurality of moveable elements, each of which basically comprises a top sunshade slat (1), fixed to the top edge of which is a pane (5).

4. The system according to claim 3, characterized in that each pane (5) is substantially perpendicular to the corresponding sunshade slat (1).

5. The system according to claim 3, characterized in that each moveable element is equipped with two end fixing elements or gusset plates (3), designed to fix the sunshade slat (1) and the pane (5) to one another, as well as a bottom sectional strip (2), designed to support the bottom edge of the pane itself.

6. The system according to claim 5, characterized in that said connection gusset plates (3) are rotateably inserted, by means of idle pins, in a side frame (4), which is for supporting the moveable elements themselves comprising the sunshade slats (1) and the panes (5).

7. The system according to claim 6, characterized in that the top end of each pane (5) is designed to be inserted in a rear slot of the corresponding sunshade slat (1), whilst the bottom end is designed to be inserted in a bottom sectional strip (2) and blocked therein with a purposely provided glass stop (6) and a weather strip (7).

8. The system according to claim 7, characterized in that the moveable facade elements, supported by the frame (4), are fixed to an upright (8), which is in turn fixedly anchored to the building in a known way.

9. The system according to claim 8, characterized in that the movement of the moveable elements, and consequently of the sunshade slats (1), is obtained via a purposely provided motor or other manual member (9).

10. The system according to claim 9, characterized in that said motor (9) or manual member is equipped with a crank mechanism, which on one side is fixed to a connection rod (11), which connects the ends of the various moveable elements of each facade element, and on the other is fixed to a metal bracket (10), which is in turn fixed to the upright (8).

11. The system according to claim 7, characterized in that, in order to guarantee air tightness and water tightness in the winter period, the bottom sectional strip (2) for supporting the pane (1) is equipped with a drip, and is designed to bear upon the sectional strip of the underlying sunshade slat (1) via a purposely provided gasket (13).

12. The system according to claim 5, characterized in that, in the winter period, it is designed to be set in a closed position, i.e., with the sunshade slats (1) in a substantially horizontal position and the panes in a vertical position to provide a double-skin facade; thus obtaining that the sun's rays, with low inclination with respect to the horizon, are intercepted only to a minimum extent by the sunshade slats (1), heating the air in the gap between the panes (5) and the outer facade of the building.

13. The system according to claim 5, characterized in that, in the summer period, it is designed to be set in an open position, i.e., with the sunshade slats (1) rotated by an amount necessary for intercepting the sun's rays and for keeping the outer wall of the building in the shade; thus obtaining that the sun's rays, with high inclination with respect to the horizon are intercepted completely or almost completely by the sunshade slats (1), so that the air in the gap between the panes (5) and the outer facade of the building does not undergo any heating by the sun or undergoes an altogether negligible degree of heating.

14. The system according to claim 11, characterized in that the rotation of the sunshade slats (1) and of the panes (5) fixed thereto is obtained by acting on means of movement (9 and 11) actuated by a purposely provided motor or by a manual control.

15. The system according to claim 2, characterized in that the sunshade slats (1) are made of extruded aluminium sectional strip or plastic material, or wood, or other suitable material.

16. The system according to claim 5, characterized in that the side gusset plates (3), which mechanically join the sunshade slats (1), the pane (5), and the bottom sectional strip (2), which supports it, have the shapes and dimensions desired or required by the particular application, and are made of plastic material, aluminium, or any other suitable material.

17. The system according to claim 2, characterized in that the sunshade slats (1) comprise photovoltaic panels for the conversion of solar radiation into electrical energy.

18. The system according to claim 10, characterized in that the weather stripping (7) and the contact gaskets (13) are designed to enable hermetic closing of said panes (5) on the side supporting frame (4) in order to constitute a shield for the outer walls of the buildings.

19. The system according to claim 2, characterized in that said panes (5) are of various dimensions and types: stratified, tempered, stratified and tempered, transparent, coloured, low-emission, etc.

20. The system according to claim 2 or claim 3, characterized in that each of the sunshade slats (1) forms a single body with the corresponding pane (5) and the ensemble can turn on a supporting frame (4) via pins that enable its rotation and corresponding orientation.

21. The system according to claim 20, characterized in that the sunshade slats (1) and the pane (5) that form a single body are connected in series by means of a crank mechanism that enables the simultaneous orientation of the elements made up of a plurality of sunshade slats and of corresponding panes.

22. (cancel)
